(19) United States
(12) Patent Application Publication
(10) Pub. No.: US 2008/0018344 A1
(43) Pub. Date: Jan. 24, 2008

(54) RF Bridge Circuit Without Balun Transformer

(76) Inventor: Stephen P. Jachim, Portland, OR (US)

Correspondence Address: Jeffrey C. Hood;Meyertons Hood Kivlin Kowert & Goetzel PC, P.O. Box 398, Austin, TX, 78767-0398, US

(21) Appl. No.: 11/459,287

(22) Filed: Jul. 21, 2006

(51) Int. Cl. G01R 27/02; G01R 27/32; G01R 27/04

(52) U.S. Cl. 324/610; 324/648

(57) ABSTRACT

An RF bridge circuit without a balun transformer. The RF bridge circuit may include a resistive bridge and a differential detector. The resistive bridge may generate a differential signal that is indicative of a differential imbalance across the resistive bridge. Specifically, the differential signal may be indicative of the ratio of the impedance associated with a DUT and the impedance associated with a reference device. The differential detector may be connected directly to the resistive bridge and may sense the differential signal. The differential detector may convert the differential signal into a differential or single-ended IF signal. The RF bridge circuit may process the differential signal without the use of a balun transformer. The differential detector may include a balanced differential mixer, such as a diode ring, a FET quad, a Gilbert cell, and a harmonic mixer. Alternatively, the differential detector may include a balanced differential sampler, such as a harmonic sampler and a sampling bridge.

### BACKGROUND OF THE INVENTION

1. Field of the Invention

This invention relates to analog circuits and, more particularly, to RF bridge design.

2. Description of the Related Art

Conventional RF bridge designs use a balun (balanced/unbalanced) transformer to sense the differential imbalance across a resistive bridge network. These RF bridge implementations have several drawbacks. First, the physical nature of the balun makes it relatively difficult to manufacture and apply in assembly. Second, at low frequencies (e.g., <50 MHz) the balun dimensions become large, which may compromise high-frequency performance. Also, transformer baluns exhibit an inherent low-frequency performance limitation.

### SUMMARY OF THE INVENTION

Various embodiments are disclosed of an RF bridge circuit without a balun transformer. The RF bridge circuit may be connected to a device under test (DUT), and may include a resistive bridge and a differential detector. In one embodiment, when the DUT is connected to the RF bridge, the resistive bridge functionally includes a first resistor, a second resistor, a third resistor, the DUT, and a reference device. The resistive bridge may generate a differential signal that is indicative of a differential imbalance across the resistive bridge. Specifically, the differential signal may be indicative of the ratio of the impedance associated with the DUT and the impedance associated with the reference device.

In one embodiment, differential detector may be connected directly to the resistive bridge and may sense the differential signal. The differential detector may convert the differential signal into a differential or single-ended intermediate frequency (IF) signal. Then, the IF signal may be provided to processing circuitry to determine the impedance associated with the DUT.

In various embodiments, the differential detector may include a balanced differential mixer for sensing the differential signal and converting it to a differential or single-ended IF signal. The differential mixer may be one of various types of mixers, such as a diode ring mixer, a FET quad mixer, a Gilbert cell mixer, and a harmonic mixer. Alternatively, in other embodiments, the differential detector may include a balanced differential sampler. The differential sampler may be one of various types of samplers, such as a harmonic sampler and a sampling bridge.

### BRIEF DESCRIPTION OF THE DRAWINGS

FIG. 1 is a block diagram of one embodiment of a test system including an RF bridge circuit; and

FIG. 2 is a block diagram of one embodiment of the RF bridge circuit of FIG. 1.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must). The term “include”, and derivations thereof, mean “including, but not limited to”. The term “coupled” means “directly or indirectly connected”.

### DETAILED DESCRIPTION

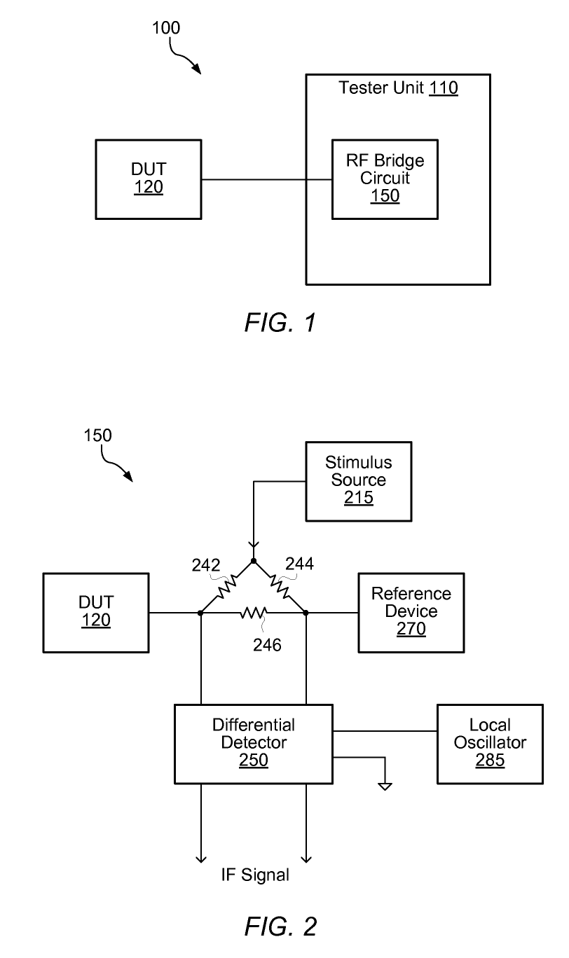

FIG. 1 is a block diagram of one embodiment of a test system 100. Test system 100 may include a tester unit 110 and a DUT 120. Tester unit 110 may include a radio frequency (RF) bridge circuit 150 for measuring the impedance associated with DUT 120. Tester unit 110 may be one of various kinds of conventional testers for testing electronics. In various applications, tester unit 110 and RF bridge circuit 150 may be used for component characterization or network analysis. It is noted, however, that tester unit 110 and RF bridge circuit 150 may be used for other applications that require measuring reflections from a DUT, e.g., characterizing a DUT by measuring reflections.

Tester unit 110 may be configured as a computer-based instrument or a stand-alone instrument. Tester unit 110 may include a computer system, which may be any of various types of computing or processing systems, including a personal computer system (PC), mainframe computer system, server system including a plurality of server blades, workstation, network appliance, Internet appliance, personal digital assistant (PDA), or other device or combinations of devices. In general, the term “computer system” can be broadly defined to encompass any device (or combination of devices) having at least one processor that executes instructions from a memory medium. The processor may be any of various types of processors, including an x86 processor, e.g., a Pentium™ class, a PowerPC™ processor, a CPU from the SPARC™ family of RISC processors, as well as others. Also, the computer system may include one or more memory subsystems (e.g., Dynamic Random Access Memory (DRAM) devices). The memory subsystems may collectively form the main memory of the computer system from which programs primarily execute. The main memory may further store user applications and driver software programs.

FIG. 2 is a block diagram of one embodiment of RF bridge circuit 150. In one specific implementation, RF bridge circuit 150 may include a resistor 242, a resistor 244, a resistor 246, a reference device 270, a differential detector 250, and a local oscillator 285. When RF bridge circuit 150 is connected to a DUT (e.g., DUT 120), resistor 242, resistor 244, resistor 246, reference device 270, and DUT 120 collectively form a resistive bridge network for RF bridge circuit 150. In the illustrated embodiment of FIG., 2, resistor 242 is connected to resistors 244 and 246. DUT 120 is connected to resistors 242 and 246, and to differential detector 250. Reference device 270 is connected to resistors 244 and 246, and to differential detector 250. Local oscillator 285 is connected to differential detector 250, and stimulus source 215 is connected to the junction of resistors 242 and 244.

During operation, the resistive bridge generates a differential signal that is indicative of a differential imbalance across the resistive bridge. More specifically, the differential signal is indicative of the ratio of the impedance associated with DUT 120 and the impedance associated with reference device 270. Differential detector 250, which is connected directly to the resistive bridge, senses the differential signal, and converts the differential signal directly into a differential or single-ended IF signal. Then, the IF signal is processed to determine the impedance associated with DUT 120. For example, in one embodiment, the IF signal may be resolved into in-phase and quadrature components, and other conventional mathematical operations may be performed to determine the impedance of DUT 120.

Furthermore, local oscillator 285 may drive the differential detector 250 and stimulus source 215 may drive the resistive bridge. Reference device 270 may include a variable resistance (e.g., a potentiometer) and may be programmable to perform the necessary measurements. In some embodiments, the resistive bridge may fundamentally operate similar to a Wheatstone bridge. It is noted, however, that in other embodiments the resistive bridge may have other characteristics.

In various embodiments, differential detector 250 includes a balanced differential mixer for sensing the differential signal and converting it to a differential or single-ended IF signal. The differential mixer may be one of various types of mixers, such as a diode ring mixer, a FET quad mixer, a Gilbert cell mixer, and a harmonic mixer, among others. In other embodiments, differential detector 250 includes a balanced differential sampler. The differential sampler may be one of various types of samplers, such as a harmonic sampler and a sampling bridge, among others.

Prior art RF bridges circuits typically include a balun (balanced/unbalanced) transformer directly coupled to a resistive bridge. In these prior art systems, the balun transformer usually converts the differential signal to a ground-referenced signal. The balun transformer then provides the signal to a single-sided mixer or sampler to initiate the detection process and convert the signal to a lower frequency. However, as described above, these RF bridge implementations have several drawbacks. First, the physical nature of the balun makes it relatively difficult to manufacture and apply in assembly. Second, at low frequencies (e.g., <50 MHz) the balun dimensions become large, which may compromise high-frequency performance. Also, transformer baluns exhibit an inherent low-frequency performance limitation.

The implementations described above with reference to FIGS. 1 and 2 process the differential signal generated by the resistive bridge without the use of a balun. By eliminating the balun transformer, RF bridge circuit 150 has several advantages and cost savings. First, RF bridge 150 consists only of resistors and semiconductors, which makes it realizable in standard printed circuit, hybrid integrated circuit, and monolithic integrated circuit technology, among others. Second, the circuitry can be assembled using standard manufacturing processes. Also, RF bridge circuit 150 has no inherent low frequency limit. Furthermore, since the design eliminates the balun transformer, which is typically a large electromechanical structure, the circuitry may take up less space.

It should be noted that the components described with reference to FIG. 2 are meant to be exemplary only, and are not intended to limit the invention to any specific set of components or configurations. For example, in various embodiments, one or more of the components described may be omitted, combined, modified, or additional components included, as desired.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. An RF bridge circuit comprising:
a resistive bridge configured to generate a differential signal indicative of a differential imbalance across the resistive bridge; and
a differential detector coupled directly to the resistive bridge and configured to sense the differential signal;
wherein the differential detector is further configured to convert the differential signal into an IF signal.

2. The RF bridge circuit of claim 1, configured to process the differential signal without the use of a balun transformer.

3. The RF bridge circuit of claim 1, wherein the differential detector includes a differential mixer core.

4. The RF bridge circuit of claim 3, wherein the differential mixer core includes a diode ring mixer.

5. The RF bridge circuit of claim 3, wherein the differential mixer core includes an FET quad mixer.

6. The RF bridge circuit of claim 3, wherein the differential mixer core includes a Gilbert cell mixer.

7. The RF bridge circuit of claim 3, wherein the differential mixer core includes a harmonic mixer.

8. The RF bridge circuit of claim 1, wherein the differential detector includes a differential sampler core.

9. The RF bridge circuit of claim 7, wherein the differential sampler core includes a harmonic sampler.

10. The RF bridge circuit of claim 7, wherein the differential sampler core includes a sampling bridge.

11. The RF bridge circuit of claim 1, wherein the resistive bridge includes a device under test (DUT) and a reference device, wherein the differential signal is indicative of the ratio of an impedance associated with the DUT and an impedance associated with the reference device.

12. The RF bridge circuit of claim 11, wherein the differential detector is operable to provide the IF signal to processing circuitry to determine the impedance associated with the DUT.

13. The RF bridge circuit of claim 1, wherein the IF signal is one of a differential IF signal and a single-ended IF signal.

14. The RF bridge circuit of claim 1, wherein, after coupling a DUT to the RF bridge circuit, the resistive bridge functionally includes a first resistor, a second resistor, a third resistor, the DUT, and a reference device, wherein the first resistor is coupled to the second and third resistors, the DUT is coupled to the first resistor, third resistor, and differential detector, and the reference device is coupled to the second resistor, third resistor, and differential detector.

15. A method for measuring an impedance of a device under test (DUT) using an RF bridge circuit, the method comprising:
generating a differential signal indicative of a differential imbalance across a resistive bridge of the RF bridge circuit;
sensing the differential signal using a differential detector coupled directly to the resistive bridge;
converting the differential signal into an IF signal using the differential detector; and
processing the IF signal to determine the impedance of the DUT.

16. The method of claim 15, further comprising processing the differential signal without the use of a balun transformer.

17. A system comprising:
a device under test (DUT); and
an RF bridge circuit coupled to the DUT, the RF bridge circuit comprising:
a resistive bridge configured to generate a differential signal indicative of the ratio of an impedance associated with the DUT and an impedance associated with a reference device; and
a differential detector coupled directly to the resistive bridge and configured to sense the differential signal;
wherein the differential detector is further configured to convert the differential signal into an IF signal.

18. The system of claim 17, wherein the RF bridge circuit is configured to process the differential signal without the use of a balun transformer.

19. The system of claim 17, wherein the differential detector includes a differential mixer core.

20. The system of claim 17, wherein the differential detector includes a differential sampler core.

21. The system of claim 17, wherein, after coupling the DUT to the RF bridge circuit, the resistive bridge functionally includes a first resistor, a second resistor, a third resistor, the DUT, and the reference device, wherein the first resistor is coupled to the second and third resistors, the DUT is coupled to the first resistor, third resistor, and differential detector, and the reference device is coupled to the second resistor, third resistor, and differential detector.
